(19) United States
(12) Patent Application Publication
(10) Pub. No.: US 2008/0157254 A1
(43) Pub. Date: Jul. 3, 2008

(54) Compound semiconductor image sensor

(75) Inventor: Yoon Mook Kang, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/984,053

(22) Filed: Nov. 13, 2007

(30) Foreign Application Priority Data
Dec. 28, 2006 (KR) 10-2006-0135900

(51) Int. Cl. H01L 27/146

(52) U.S. Cl. 257/440; 257/E27.134

(57) ABSTRACT

A compound image sensor includes a plurality of PN junction layers connected in parallel. The PN junction layers have different band gap energies, each corresponding to the absorption of light of blue, green, and red colors. The image sensor further includes oxide layers deposited between the PN junction layers to insulate the PN junction layers.

This application claims the benefit of priority to Korean Patent Application No. 10-2006-0135900, filed Dec. 28, 2006, the entire contents of which are incorporated herewith by reference.

### BACKGROUND

1. Technical Field

The present invention relates to a method for manufacturing a compound semiconductor image sensor, and more particularly, to a method for manufacturing a compound semiconductor image sensor having a photodiode with a maximized light absorption ratio.

2. Related Art

In general, an image sensor refers to a device for converting an optical image into an electrical signal. The image sensor converts light of the optical image into electrons, and obtains a voltage corresponding to an amount of the electrons accumulated at each pixel of the image sensor, the voltage depending on the intensity or wavelength of the optical image received by the pixel. In order to obtain colors of the light, the image sensor may use a color filter of three primary colors formed over the photodiode at each pixel, and determines the color of each pixel by combining the determined color with that of neighboring pixels.

The working principle of a photodiode will be described as follows. If a reverse voltage is applied to a PN junction formed in a silicon substrate, a charge depletion region is formed centering the PN junction. Photons incident to the charge depletion region may generate pairs of electrons and holes. The applied voltage moves the holes to a P-type region and moves the electrons to an N-type region. The electrons accumulated in the N-type region, which is defined as a charge accumulation region, are read out as a voltage via a suitable circuit.

In the photodiode, the absorption of photons depends on the wavelength of the light. If the wavelength is shorter, most of the light is absorbed at a surface of the silicon substrate and disappears as the light goes deeper in the silicon substrate. For example, visible light of a shorter wavelength, such as blue color light, may be absorbed by the silicon substrate with the highest efficiency within a depth of about 0.1 μm from the surface of the silicon substrate, and disappear within a depth of about 0.5 μm. Green color light, which is at the middle of the visible spectrum, penetrates the silicon substrate up to a depth of about 1.5 μm, which is a little deeper than the penetration depth of the blue color light. Red color light penetrates the silicon substrate up to about 5 μm. These penetration depths can be determined according to the light absorption coefficient of the silicon substrate. Further, spectral properties of photons at each wavelength may be determined by quantum efficiency depending on a junction structure of the photodiode formed in the silicon substrate.

FIG. 1 schematically illustrates an image sensor with color filters, in accordance with the conventional art. In an image sensor with color filters, incident light may be divided into red, green, and blue wavelength bands through the color filters. The divided wavelength bands may be converted into electrons and holes in each photodiode receiving the incident light. However, the image sensor shown in FIG. 1 requires a low photosensitivity property and a wide area.

FIG. 2 schematically illustrates an image sensor without color filters. In FIG. 2, a photodiode detects three colors in one pixel without using color filters. By forming impurity layers in the photodiode, light of different colors can be detected by the impurity layers, because the impurity layers have different light absorption rates and quantum efficiencies corresponding to different light colors.

FIG. 3 shows an equivalent circuit of the image sensor shown in FIG. 2. The image sensor absorbs light of Red, Green, and Blue (RGB) colors at different depths in the silicon substrate, and divides the absorbed light into electrical signals, using the differences of absorption coefficients for light of different wavelengths as shown in the diagram of FIG. 4.

As shown in FIG. 2, the photodiode of the conventional image sensor includes impurity layers to detect three different colors in one pixel. Therefore, an additional supplementary circuit may be required to separately process three colors in each pixel. Accordingly, the area of the pixel may be increased due to the presence of the supplementary circuit, thus making it difficult to achieve a high integration of image sensors. Also, it may be difficult to accurately distinguish RGB wavelengths, because a continuity in absorption coefficients of the impurity layers for different wavelengths leads to a continuity of absorption depths.

As shown in FIG. 5, a compound semiconductor image sensor can be formed in a compound semiconductor having a laminated structure using a multi-junction solar cell. The compound semiconductor image sensor may divide and absorb light of different wavelengths in different junction layers. However, only a minimum amount of electric current may be generated in the compound semiconductor image sensor at each junction, because the compound semiconductor image sensor include a plurality of PN junctions connected in series.

### SUMMARY

Consistent with the present invention, there is provided a method for manufacturing a compound semiconductor image sensor, for maximizing a light absorption ratio of a photodiode.

In one embodiment consistent with the present invention, there is provided a compound semiconductor image sensor including: a plurality of PN junction layers connected in parallel; and oxide layers formed between the PN junction layers to insulate the PN junction layers.

### BRIEF DESCRIPTION OF THE DRAWINGS

The above and other features consistent with the present invention will become apparent from the following detailed description given in conjunction with the accompanying drawings, in which:

FIG. 1 illustrates an image sensor with a color filter in accordance with the conventional art;

FIG. 2 illustrates an image sensor without a color filter in accordance with the conventional art;

FIG. 3 is an equivalent circuit diagram illustrating the image sensor shown in FIG. 2;

FIG. 4 is a diagram showing the light absorption coefficient of different colors versus materials and wavelengths in accordance with the conventional art;

FIG. 5 illustrates a multi-junction solar cell structure in accordance with the conventional art; and

FIGS. 6a and 6b illustrate a compound semiconductor image sensor having a multi-layer thin film structure in accordance with an embodiment consistent with the present invention.

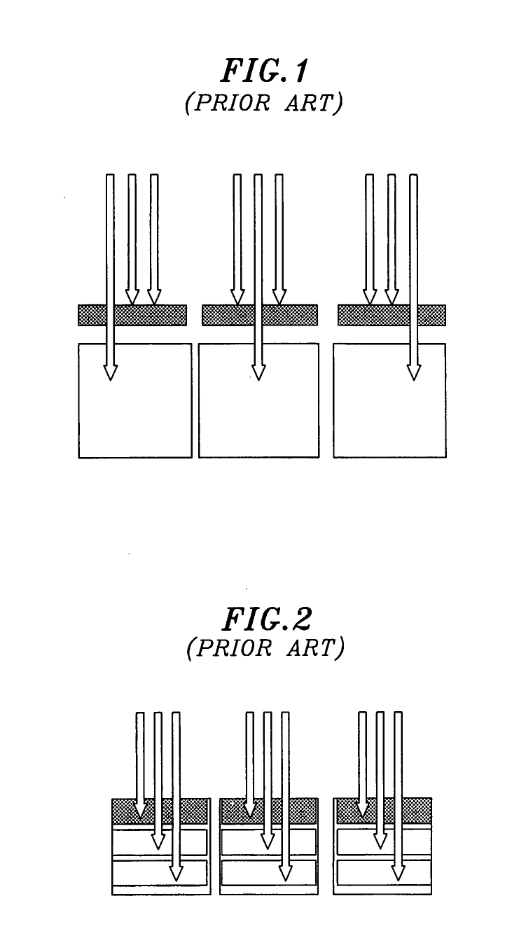

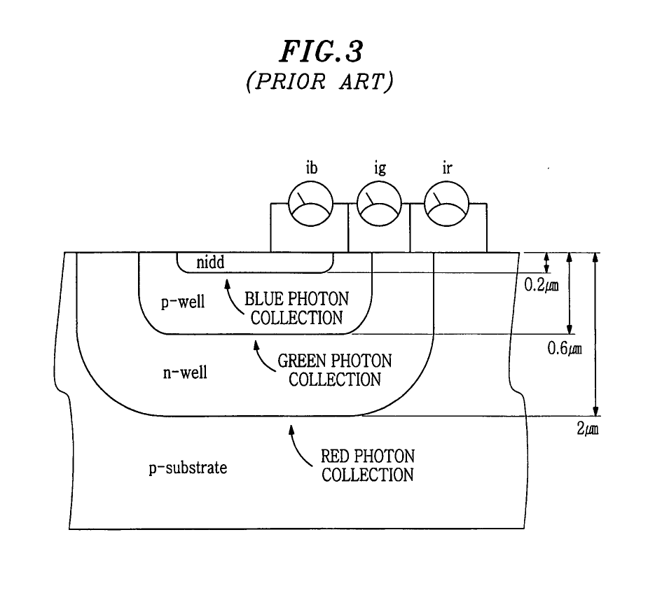

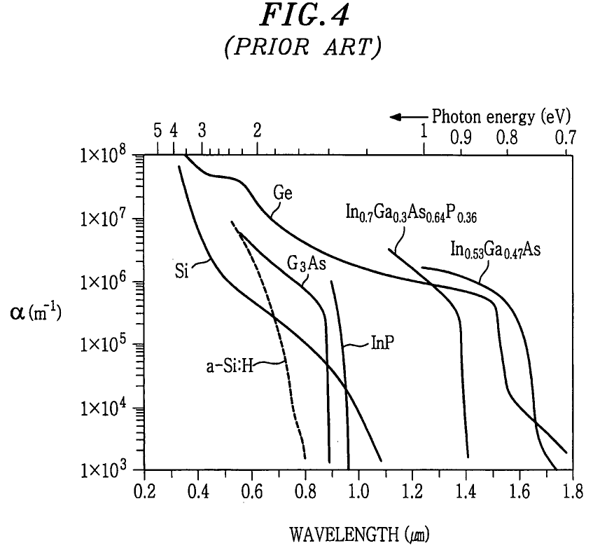

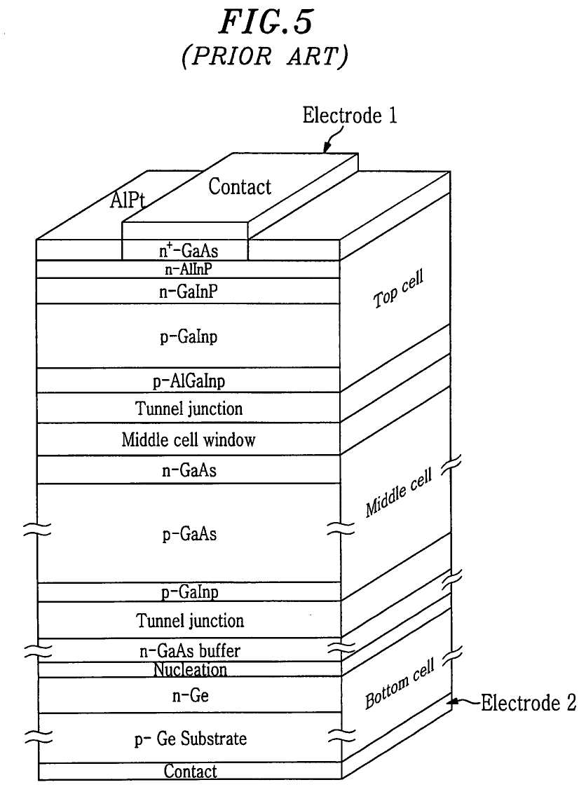

### DETAILED DESCRIPTION

Hereinafter, embodiments consistent with the present invention will be described in detail with reference to the accompanying drawings so that they can be readily implemented by those skilled in the art.

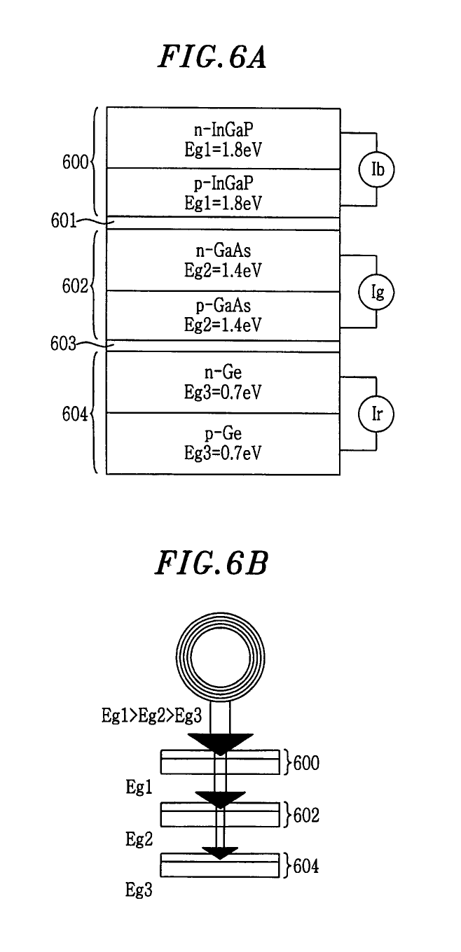

FIGS. 6a and 6b illustrate a compound semiconductor image sensor having a multi-layer thin film structure in accordance with an exemplary embodiment of the present invention.

As shown in FIGS. 6a and 6b, the compound semiconductor image sensor includes a plurality of PN junction layers 600, 602, and 604, and oxide layers 601 and 603. PN junction layers 600, 602, and 604 may be designed to have different band gap energies, each corresponding to blue, green, and red colors. Oxide layers 601 and 603, each having a predetermined thickness, may be deposited between PN junction layers 600, 602, and 604, and insulate PN junction layers 600, 602, and 604. PN junction layers 600, 602, and 604 include a first PN junction thin-film layer 600, a second PN junction thin-film layer 602, and a third PN junction thin-film layer 604. First PN junction thin-film layer 600 may comprise a p-InGaP (p-type indium gallium phosphorous) thin-film layer and an n-InGaP (n-type indium gallium phosphorous) thin-film layer formed on the -InGaP thin-film layer. Second PN junction thin-film layer 602 may comprise a p-GaAs (p-type gallium arsenide) thin-film layer and an n-GaAs (n-type gallium arsenide) thin-film layer formed on the p-GaAs thin-film layer. Third PN junction thin-film layer 604 may comprise a p-Ge (p-type germanium) thin-film layer and an n-Ge (n-type germanium) thin-film layer formed on the p-Ge thin-film layer.

First PN junction thin-film layer 600 is formed on second PN junction thin-film layer 602. First PN junction thin-film layer 600 may have a first band gap energy Eg1 of, for example, about 1.8 eV for absorbing light of relatively shorter wavelengths, such as blue color light. Second PN junction thin-film layer 602 is formed on third PN junction thin-film layer 604. Second PN junction thin-film layer 602 may have a second band gap energy Eg2 of, for example, about 1.4 eV for absorbing light of wavelengths longer than that of the blue color light. In one embodiment, second PN junction thin-film layer 602 may absorb green color light, the wavelength of which is longer than that of the blue color light. Third PN junction thin-film layer 604 may have a band gap energy Eg3 of, for example, about 0.7 eV for absorbing light of wavelengths longer than that of the green color light. In one embodiment, third PN junction thin-film layer 604 may absorb red color light, the wavelength of which is longer than that of the green color light.

An operation of the image sensor having the multi-layer thin film structure, i.e., the PN junction layers 600, 602, and 604, will be described with reference to FIGS. 6a and 6b.

First PN junction thin-film layer 600 may generate electrons and holes in the p-InGaP thin-film layer and the n-InGaP thin-film layer by selectively absorbing blue color light, thereby generating a blue color wavelength current Ib at the PN junction of first PN junction thin-film layer 600. Second PN junction thin-film layer 602 may generate electrons and holes in the p-GaAs thin-film layer and the n-GaAs thin-film layer by selectively absorbing green color light, thereby generating a green color wavelength current Ig at the PN junction of second PN junction thin-film layer 602. Third PN junction thin-film layer 604 may generate electrons and holes in the p-Ge thin-film layer and the n-Ge thin-film layer by selectively absorbing red color light, thereby generating a red color wavelength current Ir at the PN junction of third PN junction thin-film layer 604.

In other words, the compound semiconductor image sensor having a compound semiconductor thin-film laminated structure includes first, second, and third PN junction thin-film layers 600, 602, and 604, wherein each of first, second, and third PN junction thin-film layers 600, 602, and 604 has a different band gap energy for selectively absorbing light by controlling the band gap energy of each layer. Further, first, second, and third PN junction thin-film layers 600, 602, and 604 have PN junctions connected in parallel to thereby selectively acquire light currents therefrom.

As described above, therefore, the present invention provides an image sensor in a laminated structure of compound semiconductor thin films having different band gap energies. Light of different wavelengths may be selectively absorbed by controlling the band gap energy of each compound semiconductor thin film. Light currents of different light colors may be selectively acquired in the PN junctions of PN junction layers, which are connected in parallel. By doing so, the image sensor consistent with the present invention may comprise an improved photoelectric conversion efficiency by using the multi-layer thin films.

While embodiments consistent with the present invention have been shown and described, it will be understood by those skilled in the art that various changes and modifications may be made without departing from the spirit and scope of the present invention as defined in the following claims.

What is claimed is:

1. A compound semiconductor image sensor, comprising:
a plurality of PN junction layers connected in parallel; and
oxide layers formed between the PN junction layers to insulate the PN junction layers.

2. The compound semiconductor image sensor of claim 1, wherein the PN junction layers comprises:
a third PN junction thin-film layer having a third band gap energy for absorbing red color light;
a second PN junction thin-film layer formed on the third PN junction thin-film layer and having a second band gap energy for absorbing green color light; and
a first PN junction thin-film layer formed on the second PN junction thin-film layer and having a first band gap energy for absorbing blue color light.

3. The compound semiconductor image sensor of claim 2, wherein the third PN junction thin-film layer generates a red color wavelength current in response to the absorbed red color light.

4. The compound image sensor of claim 2, wherein the second PN junction thin-film layer generates a green color wavelength current in response to the absorbed green color light.

5. The compound semiconductor image sensor of claim 2, wherein the first PN junction thin-film layer generates a blue color wavelength current in response to the absorbed blue color light.

6. The compound semiconductor image sensor of claim 2, wherein the first, second, and third band gap energies are about 1.8 eV, 1.4 eV, and 0.7 eV, respectively.

7. The compound semiconductor image sensor of claim 2, wherein the first PN junction thin-film layer includes a p-InGaP thin film layer and an n-InGaP thin-film layer formed on the p-InGaP thin film layer.

8. The compound semiconductor image sensor of claim 2, wherein the second PN junction thin-film layer includes a p-GaAs thin-film layer and an n-GaAs thin-film layer formed on the p-GaAs thin-film layer.

9. The compound semiconductor image sensor of claim 2, wherein the third PN junction thin-film layer includes a p-Ge thin-film layer and an n-Ge thin-film layer formed on the p-Ge thin-film layer.
